(19) United States
(12) Patent Application Publication
(10) Pub. No.: US 2026/0134935 A1
(43) Pub. Date: May 14, 2026

(54) METHOD FOR COLLECTING VALLEY AND PEAK INFORMATION FOR DEBUGGING A MEMORY DEVICE

(71) Applicant: MICRON TECHNOLOGY, INC., BOISE, ID (US)

(72) Inventors: Tawalin Opastrakoon, Boise, ID (US); Michael G. Miller, Boise, ID (US); Gary F. Besinga, Boise, ID (US); Che Chen, Boise, ID (US)

(21) Appl. No.: 18/946,235

(22) Filed: Nov. 13, 2024

(51) Int. Cl. G11C 29/10

(52) U.S. Cl. CPC G11C 29/10

(57) ABSTRACT

A technique is disclosed for collecting peak and valley distribution information for debugging a memory device. In some examples, a read voltage from a set of read voltages is set to be applied to memory cells of the memory device. A bit count command is issued to the memory device to apply the read voltage to the memory cells to count a number of memory cells of the memory cells storing a zero bit. The setting and repeating operations are repeated until remaining read voltages of the set of read voltages have been applied to the memory cells to determine the number of memory cells storing the zero bit at each remaining read voltage applied to the memory cells. Bit count data is provided in response to the repeating operation. Debug data characterizing the peak and valley distribution information is provided based on the bit count data.

### TECHNICAL FIELD

This disclosure relates to collecting valley and peak information for debugging a memory device.

### BACKGROUND

A memory sub-system includes a memory device designed for data storage. These memory devices are implemented as non-volatile and volatile memory devices in various examples. In some such examples, a host system employs a memory sub-system for the purposes of storing data on the memory devices and for retrieving data from the memory devices. Not-AND (NAND) flash memory is a type of non-volatile storage technology used in electronic devices and computers for data storage. In NAND flash memory, data is stored in memory cells that can hold electrical charges, representing data bits.

A read level (or read voltage) in a memory device refers to a specific voltage applied to memory cells during a read operation to determine the stored data. The voltage applied is used to identify a logic state (e.g., “0” or “1”) stored in a cell by detecting how much charge the cell holds.

### BRIEF DESCRIPTION OF THE DRAWINGS

FIG. 1 illustrates an example computing system that includes a memory subsystem in accordance with some examples of the present disclosure.

FIG. 2 illustrates a debug data collector of a memory sub-system of the computing system of FIG. 1.

FIG. 3 illustrates an example of a bit count graph.

FIG. 4 illustrates an example of a graph with an approximate voltage threshold (VT) distribution.

FIG. 5 illustrates a flowchart of an example method for collecting valley and peak distribution information for VT distribution approximation.

FIG. 6 is an example of a method for retiring a bad memory block.

FIG. 7 is an example of a method for erasing user data stored at one or more blocks, including a bad memory block.

FIG. 8 illustrates an example of a computer system (a machine) in which examples of the present description may operate.

### DETAILED DESCRIPTION

This description relates to collecting valley and peak distribution information from memory cells in non-volatile memory devices (such as Not-AND (NAND) memory devices) for providing a voltage threshold (VT) distribution for the memory cells, which can be used in assessing memory device characteristics. A memory controller can apply a series of progressively increasing read voltages to the memory cells of a memory device. The memory controller can issue a bit count command to the memory device to apply each read voltage of a set of read voltages to the memory cells to count a number of memory cells of the memory cells storing a zero bit at each read voltage to produce bit count data. The memory controller can analyze the bit count data to compute peak and valley distribution information, which can be provided as debug data. The debug data can be used to provide an estimate of the VT distribution for the memory cells. For example, the estimate VT distribution can be used to evaluate a health (e.g., cell degradation or charge leakage) and/or a performance (e.g., an error rate) of the memory cells.

More generally, a memory sub-system refers to a storage device, a memory module or some combination thereof. The memory sub-system includes a memory device or multiple memory devices that store data. The memory devices can be volatile or non-volatile devices. Some examples of a memory sub-system include high density non-volatile memory devices where retention of data is desired during intervals of time where no power is supplied to the memory device. A solid-state drive (SSD) is an example of a memory sub-system that includes a non-volatile memory device(s) and a memory sub-system controller (referred to here as a controller) to manage the non-volatile memory devices. One example of non-volatile memory devices is a NAND memory device. A non-volatile memory device is a package that includes a die(s). Each such die can include a plane(s).

For some types of non-volatile memory devices (e.g., NAND memory devices), each plane includes a set of physical blocks and each physical block includes a set of pages. A page is a smallest unit that can be programmed. A page can refer to a group of memory cells (or for simplicity cells). A cell is an electronic circuit that stores information. A cell stores at least one bit of binary information and can have logic states that correlate to a number of bits being stored. The logic states are represented by binary values, such as “0” and “1”, or as combinations of such values, such as “00”, “01”, “10” and “11”. A memory array is a grid of cells organized into rows and columns. Each page can represent a subset of cells from the memory array and all cells in the page are read/written simultaneously. Thus, the memory array can be divided into multiple pages, wherein each page includes a subset of cells of the memory array. In other examples, the page includes all of the cells of the memory array.

The cells can be arranged in a two-dimensional or a three-dimensional grid. In some examples, the memory cells are formed on a silicon wafer in an array of columns connected by conductive lines (also referred to as bitlines, or BLs) and rows connected by conductive lines (also referred to as wordlines or WLs). A wordline has a row of associated memory cells in a memory device that are used with a bitline or multiple bitlines to generate an address of each of the memory cells. The intersection of a bitline and a wordline defines an address of a given memory cell. Each memory cell of each memory array can be a single-level cell (SLC) or a higher-order cell (also known as multi-level cells), which can store multiple bits per cell (different logic states). Example of higher-order cells can include multi-level cells (MLCs), triple-level cells (TLCs), quad-level cells (QLCs), penta-level cells (PLC's) or higher-level cells. In some examples, each page that represents the group of memory cells can be spread across multiple wordlines in the memory array, and these cells can be accessed together for read and write operations.

A block (or a memory block) refers to a unit of the memory device used to store data. A block is a smallest erasable unit in a memory device, such as a NAND memory device. In various examples, the erasable unit could be implemented as a group of memory cells, a wordline group, a wordline or as individual memory cells. Multiple blocks can be grouped together to form separate partitions (e.g., planes) of the memory device to enable concurrent operations to take place on each plane.

Memory blocks can be formed by grouping pages, wherein each page contains (holds) a certain amount of data (e.g., 4 kilobytes (KB) to 16 KB per page). Thus, a memory block can consist of multiple pages. In NAND memory devices, reading and writing operations can be performed at a page level (e.g., data is accessed and written page by page). Data can be erased at a block level (e.g., all pages within the memory block are erased together).

In multi-level NAND memory devices (e.g., MLCs, TLCs, QPLCs, or higher-level cells), each memory cell can store more than one bit of information and thus NAND memory devices can include one or more different page types. Pages can be classified based on how the memory cells of that page are used for data storage. For multi-level cells, page types can include a lower page and an upper page, as an example. In single-level NAND memory devices (e.g., SLCs), there is no distinction between page types as each cell stores a single bit (0 or 1).

Each memory cell has a voltage threshold, which is the minimum voltage required for the cell to conduct and reveal the logical state stored in that cell. This voltage threshold depends on the amount of charge stored in the cell. Each logical state (e.g., “00,” “01,” “10,” or “11” in a multi-level cell) is associated with a specific range of voltage thresholds. To accurately read the stored logical state, the memory controller applies a group of read voltages that fall within that voltage threshold range, referred to as a state-specific read voltage range. Because not all cells behave the same, the group of read voltages is applied to ensure that cells with that logical state can be correctly interpreted. The memory controller applies a range of read voltages (a set of read voltages), which include multiple state-specific read voltage ranges. This set of read voltages can be referred to as a “read voltage window,” which covers the possible voltage ranges (the group of read voltages) needed to accurately read stored logical state across the memory cells.

For example, to write data to a page of the memory block, such as data from a host system, referred to herein as host data (or user data), the memory sub-system controller is configured/programmed to encode the host data and in some instances other data, as part of a write operation, into a format for storage at the memory device(s). Encoding refers to a process of generating parity bits from embedded data (e.g., a sequence of binary bits) corresponding to the host data using an error correction code (ECC) and combining the parity bits with the embedded data to generate a Low Density Parity Check (LDPC) codeword. LDPC encoding refers to an encoding method that utilizes an LDPC code to generate the parity bits, which can be referred to as a parity codeword. The user data (e.g., embedded data) is combined with the parity codeword to form the LDPC codeword, which may alternatively be referred to simply as a codeword. The codeword is storable at the memory device(s) of the memory sub-system, such as at a page of the memory block. Each page of the memory block can store one or more codewords depending on page and codeword size.

In NAND memory devices, data (e.g., codewords) is stored in pages, with each memory cell storing data using different charge levels corresponding to specific logical states (e.g., 0 s, 1 s, or multiple bits in multi-level cells). During write operations, data is randomly distributed across cells to balance logical states and prevent overuse of specific charge levels. This helps reduce localized stress on cells, contributing to a more uniform wear pattern at the page level and aiding in wear leveling at the block level. Wear leveling is a technique that is used so that memory blocks experience similar usage over time by distributing program/erase (P/E) cycles evenly across blocks. This prevents any single block from wearing out prematurely, extending an overall lifespan of the memory device. Dynamic wear leveling, for example, redistributes new data to less-used blocks to prevent concentrated wear.

Each logical state stored in a memory cell has an approximately equal probability of being used because, in most data storage systems, data is statistically random. This randomness ensures that each charge levels is used evenly, contributing to uniform wear across the memory device and improving device reliability. Data is written across pages and blocks using wear-leveling techniques to tune reliability and longevity. The controller distributes data to balance wear and prevent any block from wearing out prematurely. Randomizing data (e.g., via data scrambling) further ensures that different logical states are evenly distributed across memory cells, reducing the risk of localized wear. Additionally, in some instances, ECC and wear leveling cooperate to minimize stress on memory blocks and extend a lifespan of the memory blocks.

Despite efforts such as wear leveling, memory cells will eventually degrade after many P/E cycles. Degraded memory blocks that can no longer store data reliably are retired in memory devices, such as NAND memory devices. When a block reaches an end of a usable lifespan or exhibits excessive errors, such as a NAND program status fail, an erase status fail, or an uncorrectable read error, the controller marks the block as a bad block and retires the block, after which the block can be known as a retired block or an unreliable block.

The controller maintains a bad block table (BBT), which tracks blocks that are no longer usable to ensure that no further data is written to these blocks. If a block is flagged as bad, the controller can use a redundancy mechanism, such as a replacement (or spare) block, to continue storing data reliably without impacting performance of the memory device. As blocks are retired, the controller allocates spare blocks to replace the retired block, ensuring that a total available storage capacity remains for the host system. The controller prevents any future attempts to use retired blocks by redirecting read or write operations to the replacement blocks.

The controller (e.g., firmware of the controller) can monitor a health of each block by tracking a number of P/E cycles and/or detecting errors during read/write operations. If errors occur that cannot be corrected by ECC (e.g., uncorrectable read errors), or if the controller fails to successfully program or erase a block (e.g., indicated by a program or erase status fail), the controller marks that block as bad and updates the BBT accordingly.

For example, if the controller determines a block is a bad block, the controller initiates a block retirement process to retire the bad block. In some instances, based on NAND memory device requirements, during this process, data from the bad block can be transferred to a healthy block (the spare block). Thus, in some instances, the controller can implement a relocation process to read the data from the failing (bad) block, if needed, correct any errors in the read data, and write the read data to the spare block.

Once the read data has been transferred to the spare block, the BBT is updated so that the bad block is not used in future operations. In some examples, the data is not transferred from the bad block to the healthy block, such as in instances in which the data at the bad block is deemed unrecoverable. In such cases, the controller marks that block as bad and updates the BBT so the bad block is not used in future operations. In some examples, the controller can notify the host system that the block is bad or has been retired. For example, the controller can update logs that are accessible by the host system, informing the host system that the block has been retired due to failures.

In some scenarios, the host system can issue an erase command to the memory controller to execute an erase process to remove the host data from one or more blocks, including an unusable block (the bad block). Example erase commands can include, but are not limited to, a secure erase command, a sanitize erase command and a Non-Volatile Memory (NVM) format command. The secure erase command can be used to delete data from the memory device so that data cannot be recovered and thus the user data of the memory device is wiped. The sanitize erase command can be used to erase the user data from the memory device, including residual data that may remain even after standard deletion or formatting operations, resulting in a wipe of data from the memory device. The NVM format command can be used to reset or reformat the memory device, which involves erasing data stored on the device, including user data and system-level information.

In some examples, in response to the erase command, the controller can reset charge levels of each memory cell of one or more blocks (including the bad block), which can be referred to as target blocks, to a uniform state, typically representing an erased state. After executing the erase command, cells in the target blocks can be reset to a single erased voltage threshold.

Retired memory blocks are often analyzed to determine (diagnose) a root cause of failure, known as a debugging process. The debugging process is used to determine what caused the memory block to fail (or be retired). To debug the retired memory block, a voltage threshold (VT) distribution is needed for root cause failure identification. Generally, a VT distribution for the retired block (all memory cells of the block) or for each page (a subset of the memory cells) of the bad block is collected using a VT sweep process. The VT sweep process is used to provide the VT distribution by applying the set of read voltages to the memory cells of the retired memory block and recording a number of cells that become conductive at each read voltage. The set of read voltages covers each possible read voltage ranges for different logical states that can be stored at the memory cells of the retired memory block.

In some instances, the VT sweep process is implemented during the debugging process, for example, when the memory sub-system is not in use. For example, during the debugging process, a VT sweep (VS) command is issued to the controller. This command can be manually issued by an engineer through a script or debugging software. The VT sweep command is issued to collect 1 s and 0 s bit counts by sweeping a read level over a read voltage window (the set of read voltages) using a NAND read command for each read level. However, depending on a sweep range (e.g., whether the entire read voltage window is swept, or some portion thereof) and a read level (voltage) step size, collecting the VT distribution could take a significant amount of time and require a large amount of memory to store VT distribution information.

In yet other instances, the VT sweep process can be implemented by the controller, for example, when the memory sub-system is operational (e.g., in use), In such examples, the controller generates the VT distribution by applying the set of read voltages to the memory cells of the unusable block and recording a number of cells that become conductive at each read voltage corresponding to collecting 1 s and 0 s bit counts. However, implementing the VT sweep process in such examples requires an extensive amount of time, as the controller must apply all of the read voltages of the read voltage window to the cells of the unusable block, as this requires multiple read operations (e.g., NAND read operations) at each read voltage (read level).

Given a large number of pages (and thus memory cells) in the retired block and small step sizes between read levels, the VT sweep process is time-intensive. Furthermore, the VT sweep process requires an extensive amount of memory to store data generated during this process. For example, for each read voltage applied, the controller must record bit counts (e.g., the number of 1 s and 0 s) stored in the memory cells. Since this process is repeated across the entire read voltage window (the set of read voltages), the amount of data generated grows exponentially, especially for blocks with many pages.

As such, in some instances, the VT sweep process produces a large amount of data stored in a local memory of the controller and thus consumes considerable memory resources. Because the controller handles large amounts of data generated during the sweep and store the data in local memory, the memory sub-system can experience memory resource bottlenecks. This can reduce an availability of the memory device for regular operations, further degrading a system's throughput and responsiveness.

Moreover, the VT sweep process can significantly impact an overall performance of the memory sub-system. For example, during the VT sweep process, the controller can dedicate resources to executing multiple read operations (e.g., NAND read operations) for collecting the VT distribution, which prevents the controller from performing other operations, such as handling host read and write requests. This results in increased latency and delays in processing normal data transactions. Moreover, a processing power required to execute multiple voltage sweeps and record bit counts adds to a controller's workload, potentially slowing down other tasks. As the VT sweep process consumes both computational and memory resources this can temporarily reduce a performance of the memory sub-system, especially if the system is under heavy load or managing other tasks concurrently.

The VT distribution produced in response to the VT sweep process represents the read voltages (or read levels) at which the memory cells of the retired block became conductive representing or corresponding to all possible logical states that are stored by the memory cells of the retired block. As such, the VT distribution characterizes how read voltages are spread across the cells of the retired block. Each data point on the VT distribution represents a number of memory cells that became conductive at a specific read voltage level. These data points, when grouped together, form a distribution portion. The distribution curve includes a range of read voltages (a state-specific read voltage range) at which a subset of memory cells of the retired block conducted to represent a particular logical state. Thus, each distribution portion reflects how the cells for a specific logical state are spread across a specific range of voltages (the state-specific read voltage range) within an overall read voltage window.

Peaks and valleys in the VT distribution represent variations in a number of memory cells that become conductive at different read voltage levels. A peak of each distribution portion indicates a voltage level where a large number of cells conduct, showing a high concentration of memory cells that store a specific logical state. These peaks typically align with read voltage ranges for different logical states. Each peak corresponds to a voltage level where the majority of cells storing a particular logical state become conductive. A valley represents a voltage level where very few or no memory cells conduct. Valleys occur between the peaks and mark transitions between the voltage ranges for different logical states. Thus, valleys show gaps between the charge distributions of different logical states, indicating areas where no specific logical state is stored by the memory cells.

When cell degradation is minimal, a spacing between the peaks on the VT distribution associated with different logical states are distinct (separated) and there is no overlap between read voltages for different logical states being stored in the memory cells. Over time, as the memory cells wear out, the VT distribution can shift or broaden. Shifts, overlaps, or irregularities in the VT distribution can indicate issues such as cell degradation, charge leakage, or other memory health concerns. For example, a shift in the VT distribution occurs when the entire distribution moves horizontally, either to higher or lower voltages, often due to cell degradation or charge leakage. A broadening of the VT distribution happens when a range of voltages required to make cells conductive expands, causing the distribution portions to spread wider.

By analyzing the VT distribution of the retired block, such as during the debug process, engineers can identify a cause of failure (the root cause of failure) for the retired memory block. However, the erase process, such as those triggered by secure erase, sanitize erase, or similar erase commands impacts an ability to collect the VT distribution for the retired block making root cause of failure identification difficult for the retired block.

For example, once an erase command is executed on the unusable block (retired block), charge levels in the memory cells in the retired block are reset to a uniform erased state (a default logical state). By erasing the unusable block before collecting the VT distribution, any information about the previous state of the cells is lost, making the identification of the root cause of failure for that block difficult. This is because a VT distribution generated based on an erased bad block no longer reflects actual charge levels that were present when the block had been deemed a bad block (a failed block). Instead, the VT distribution generated after the erase process only represents a uniform erased logical state, which provides limited insight into the read voltages or logical states that were originally stored in the cells of the retired block, thereby rendering the use of a VT distribution ineffective for debugging.

Accordingly, while VT distribution collections can be performed during normal operation or during the debugging process, there are drawbacks. In memory sub-systems (e.g., in an SSD) where the VT distribution is collected before a block is erased or retired this requires substantial controller resources, which results in latency, performance impacts, and a need for extensive controller memory to store generated data (the VT distribution). In some cases, the VT distribution is not collected by the controller before an unusable block is erased. In such scenarios, any VT distribution generated during the debugging process or after a block erase is inaccurate and does not reflect a block's logical state (when the block was deemed a bad block), making root cause failure determination challenging (near impossible).

According to the examples, systems and methods are described for collecting peak and valley distribution information from memory cells of a memory device, such as a NAND memory device. For example, a memory controller can set a read voltage from a set of read voltages to be applied to memory cells of a memory device. The memory controller can issue a bit count command to the memory device to apply the read voltage to the memory cells to count a number of memory cells of the memory cells storing a zero bit. The memory controller can repeat the setting and issuing steps for remaining read voltages of the set of read voltages to determine the number of memory cells storing the zero bit at each remaining read voltage applied to the memory cells. The memory controller can receive bit count data in response to the repeating and output (provide) debug data characterizing peak and valley distribution information for the memory cells based on the bit count data.

In some examples, the memory controller evaluates each read voltage applied to the memory cells relative to one or more thresholds to identify read voltages associated with one or more peaks of a VT distribution for the memory cells corresponding to peak read voltages and identifies read voltages associated with one or more valleys of VT distribution for the memory cells corresponding to valley read voltages. The memory controller can provide an estimate VT distribution for the memory cells based on the valley and peak read voltages. In some examples, the estimate VT distribution is provided during a debugging process (e.g., when the memory controller is in a debug mode), in other examples, while the memory controller is in use. In some examples, for each of the valley and peak read voltages the memory controller can determine a bit count value. The bit count value can represent the number of memory cells of the memory cells that store a respective logical state of logical states at a corresponding read voltage of the set of read voltages applied to the memory cells. The memory controller can provide the estimate VT distribution further based on bit count values for the valley and peak read voltages.

Using the bit count command to record a number of zero bits at each applied read voltages reduces a need for large data transfers typically required during use of normal read operations (e.g., NAND read operations) for VT distribution generation, thereby reducing a time required to collect VT distribution information. Instead, the memory device (e.g., a local media controller on the memory device) reports a zero-bit count for each applied read voltage, curtailing data transfer between the memory controller and the memory device. As a result, a time needed to collect VT distribution information is reduced because the memory controller does not need to perform a full data read or transfer large amounts of read-back data from the memory cells.

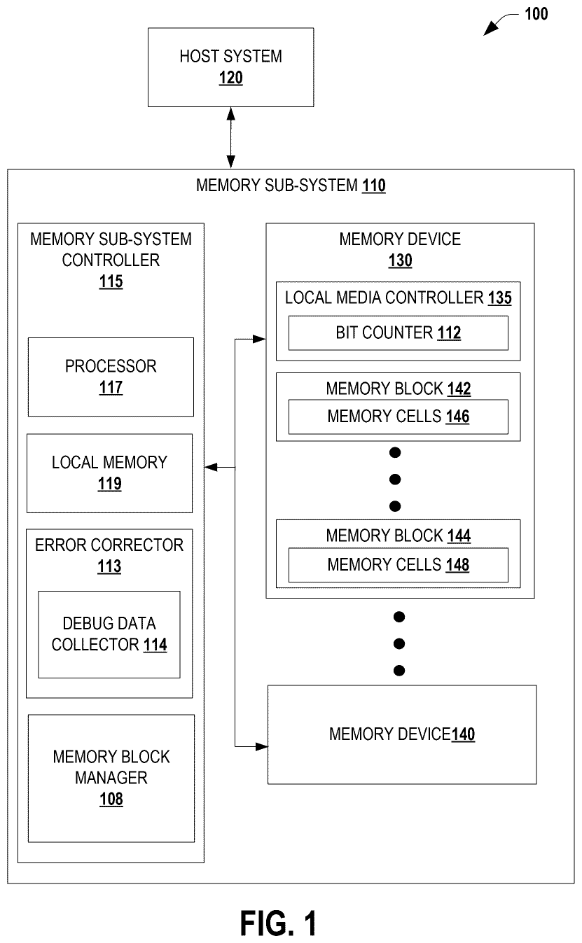

FIG. 1 illustrates an example computing system 100 that includes a memory subsystem 110 in accordance with some examples of the present disclosure. The memory subsystem 110 can include media, such as one or more volatile memory devices (e.g., memory device 140), one or more non-volatile memory devices (e.g., memory device 130), or a combination of such. The memory sub-system 110 can be a storage device, a memory module or a hybrid of a storage device and a memory module. Examples of a storage device include an SSD, a flash drive, a universal serial bus (USB) flash drive, an embedded Multi-Media Controller (eMMC) drive, a Universal Flash Storage (UFS) drive, a secure digital (SD) card and a hard disk drive (HDD). Examples of memory modules include a dual in-line memory module (DIMM), a small outline DIMM (SO-DIMM) and various types of non-volatile dual in-line memory modules (NVDIMMs).

The system 100 can be a computing device such as a desktop computer, laptop computer, network server, mobile device, a vehicle (e.g., airplane, drone, train, automobile or other conveyance), Internet of Things (IoT) enabled device, embedded computer (e.g., one included in a vehicle, industrial equipment or a networked commercial device) or such computing device that includes memory and a processing device. The system 100 can include a host system 120 that is coupled to one or more memory sub-systems 110. In some examples, the host system 120 is coupled to different types of the memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller) and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface, or any other interface.

The physical host interface can be used to transmit data between the host system 120 and the memory sub-system 110. The host system 120 can further utilize an NVM Express (NVMe) interface to access the memory components (e.g., memory device(s) 130) when the memory sub-system 110 is coupled with the host system 120 by the physical host interface (e.g., a PCIe or CXL bus). The physical host interface can provide an interface for passing control, address, data and other signals between the memory sub-system 110 and the host system 120. FIG. 1 illustrates a memory sub-system 110 as an example. In general, the host system 120 can access multiple memory sub-systems via a same communication connection, multiple separate communication connections and/or a combination of communication connections.

The memory device 130 and the memory device 140 are implemented as non-transitory computer readable media. The memory device 130 and the memory device 140 can include any combination of the different types of non-volatile memory devices and/or volatile memory devices. The volatile memory devices (e.g., the memory device 140) can be, but are not limited to, random access memory (RAM), such as dynamic random access memory (DRAM) and synchronous dynamic random access memory (SDRAM).

Some examples of non-volatile memory devices (e.g., memory device(s) 130) include NAND type flash memory and write-in-place memory, such as three-dimensional cross-point (“3Dcross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2DNAND) and three-dimensional NAND (3DNAND).

Although non-volatile memory components such as a 3Dcross-point array of non-volatile memory cells and NAND type flash memory (e.g., 2DNAND, 3DNAND) are described, the memory device 130 can be based on any other type of non-volatile memory, such as read-only memory (ROM), phase change memory (PCM), self-selecting memory, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-OR (NOR) flash memory, electrically erasable programmable read-only memory (EEPROM), etc.

In some examples, a non-volatile memory device is a package of one or more dies. The dies in the packages can be assigned to one or more channels for communicating with the controller 115. Each die can consist of one or more planes. Planes can be grouped into logic units (LUN). For some types of non-volatile memory devices (e.g., NAND memory devices), each plane consists of a set of physical blocks, which are groups of memory cells to store data.

For example, each of the memory device(s) 130 and 140 include one or more memory blocks 142-144 (for simplicity blocks 142-144). Each block 142-144 can include memory cells 146-148 (also referred to as cells 146-148). A cell is an electronic circuit that stores information. In some examples, the memory blocks 142-144 include pages that can store all or a portion of the memory cells. For example, each page of each memory block 142-144 can include a group of memory cells, in some instances, corresponding to the memory cells 146-148, respectively.

In some instances, the memory cells 146-148 of the memory device 130 can be grouped as pages that can refer to a logical unit of the memory device used to store data. In some types of memory (e.g., NAND), each of the respective blocks 142-144 can be formed of multiple pages and each of the pages can include a portion of memory cells of the memory cells 146-148. The memory devices 130 and 140 are structured to include wordlines. Wordlines are addressable wiring lines that connect and control a row of memory cells (of a respective page) in the memory device 130 and 140. Each wordline addresses one or more cells of the cells 146-148 in a corresponding row contemporaneously, enabling operations such as reading, writing and erasing data.

Memory cells 146-148 of one of the memory blocks 142-144 can store bits (corresponding to logical states). A logic state stored at a cell correlates to a number of bits being stored. Each logic state can be represented by binary values, such as “0” and “1”, or combinations of such values. One type of memory cell, for example, SLC can store one bit per cell. Other types of memory cells, such as MLCs, TLCs, QLCs, PLCs and higher order memory cells, can store multiple bits per cell. In some examples, each of the memory devices 130 and 140 can include one or more arrays of memory cells such as SLCs, MLCs, TLCs, QLCs, PLCs or some combination thereof. In some examples, a particular memory device can include an SLC portion, an MLC portion, a TLC portion, a QLC portion and/or PLC portion of memory cells.

To perform operations such as reading, writing or erasing data at the memory devices 130 and other such operations, a memory sub-system controller 115 (or controller 115 for simplicity) communicates with the memory device(s) 130 and 140. The memory sub-system controller 115 can include hardware such as one or more integrated circuits and/or discrete components, a buffer memory or some combination thereof. The hardware can include a digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.) or other suitable processor.

The memory sub-system controller 115 can include a processing device, which includes one or more processors (e.g., the processor 117), configured to execute instructions stored in a local memory 119. In the illustrated example, the local memory 119 of the memory sub-system controller 115 includes an embedded memory configured to store instructions for performing various processes, operations, logic flows and routines that control operation of the memory sub-system 110, including handling communications between the memory sub-system 110 and the host system 120. The local memory 119 is a non-transitory computer-readable medium.

In some examples, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another example, a memory sub-system 110 does not include a memory sub-system controller 115 and can instead rely upon external control (e.g., provided by an external host, or by a processor or controller separate from the memory sub-system).

The memory sub-system controller 115 can receive commands from the host system 120, which can be referred to as host commands. The controller 115 can convert the host commands into instructions or appropriate commands to achieve a desired access to the memory devices 130, such as reading, writing, and/or erasing data. The memory sub-system controller 115 can be responsible for other operations such as wear leveling operations, garbage collection operations, error detection and ECC operations, encryption operations, caching operations and address translations between a logical address (e.g., a logical block address (LBA), namespace) and a physical address (e.g., physical block address (PBA)) that are associated with the memory devices 130 and 140.

The memory sub-system controller 115, for example, may employ a Flash Translation Layer (FTL) to translate logical addresses to corresponding physical memory addresses, which can be stored in one or more FTL mapping tables. In some instances, the one or more FTL mapping tables can be referred to as a logical-to-physical (L2P) mapping table and can store L2P mapping information. An L2P mapping table maps LBAs to PBAs on a page or block level. The memory sub-system controller 115 can further include host interface circuitry to communicate with the host system 120 via the physical host interface. The host interface circuitry can convert the host commands received from the host system 120 into command instructions to access the memory devices 130 as well as convert responses associated with the memory devices 130 into information for the host system 120.

The memory sub-system 110 can also include additional circuitry or components that are not illustrated. For example, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some examples, the memory devices 130 and 140 include local media controllers 135 that operate in concert with the memory sub-system controller 115 to execute operations on one or more memory cells of the memory devices 130 or 140, such as the cells 146-148. An external controller (e.g., the memory sub-system controller 115) can externally manage the memory device 130 (e.g., perform media management operations on the memory device 130). In some examples, the memory sub-system 110 is a managed memory device, which is a raw memory device 130 having control logic (e.g., local media controller 135) on the die and a controller (e.g., the memory sub-system controller 115) for media management within the same memory device package. An example of a managed memory device is a managed NAND (MNAND) device.

In some examples, the memory sub-system 110 includes an error corrector 113 that executes error-handling of data read from the memory device 130 and/or the memory device 140. In operation, the host system 120 manages and controls a flow of data between itself and the memory sub-system 110, ensuring efficient data storage and retrieval operations. More generally, the host system 120 employs the memory sub-system 110 to write data to and read data from the memory sub-system 110, as well as to erase the data. For instance, the host system 120 processes these requests for reading and/or writing data by interacting with the memory sub-system 110, managing the flow of data to and from the memory device 130 and/or the memory device 140 within the memory sub-system 110. This reading and writing of data enables operation of computing systems where data access and management are needed.

For example, in some instances, the controller 115 can retrieve or receive data from the host system 120, which can be referred to as host data or user data herein. For example, the host system 120 can issue a write command to the controller 115 to write the host data to the memory device 130. The host data can be stored in the one or more memory blocks 142-144 of the memory device 130, as an example. The error corrector 113 is configured/programmed to encode the host data and other data, as part of a write operation, into a format for storage at the memory device(s).

Encoding refers to a process of generating parity bits from the host data (e.g., a sequence of binary bits) using an ECC and combining the parity bits to embedded data (the host data) to generate an LDPC codeword (or simply codeword). The codeword is storable at the memory device(s) of the memory sub-system. In some examples, two or more codewords can be generated based on the host data for storage at the memory device 130 or 140. In some examples, one or more codewords can be used to contain the host data, which can be stored across one or more memory blocks of the memory device 130.

For example, to write the codeword to the block 142, the controller 115 communicates with the local media controller 135, which manages (direct) operations on the memory cells 146 of the blocks 142 of the memory device 130. The local media controller 135 executes one or more commands issued by the controller 115, including specifying a location (address) within the block 142 where the codeword will be stored. The controller 115 issues a program command to write the host data (encoded in one or more codewords) to the memory device 130. The local media controller 135 can program the codeword into the memory cells 146 in response to the program command. The local media controller 135 manages low-level operations on the memory cells 146-148 of corresponding blocks 142-144 including programming the memory cells 146 with appropriate charge levels corresponding to one or more bits of the codeword in response to the program command.

The local media controller 135 programs the memory cells 146 by setting (adjusting) charge levels of the memory cells 146, which can represent one or more bits of the codeword. In multi-level cells (MLC, TLC, QLC, PLC, etc.), where each cell stores multiple bits, the local media controller 135 adjusts the charge levels in each cell of the cells 146 to represent various logic states corresponding to multiple bits of the codeword. For example, the local media controller 135 can apply program voltages (or programming pulses) to the cells 146 until appropriate charge levels are achieved to store corresponding bits of the codeword at the cells 146. These bits are stored across the memory cells 146. Once the programming is complete, the codeword can be referred to as stored data (stored user data) or as a stored codeword in the memory cells 146.

The local media controller 135 can verify the stored codeword by reading back charge levels from the memory cells 146 to confirm that the read-back charge levels match corresponding bits of the codeword. ECC can be used to correct any discrepancies that may arise during programming. After programming the cells 146 with the codeword, the controller 115, in coordination with the local media controller 135, updates the L2P mapping table, associating a logical address with a physical location of the memory block 142 that stores the codeword. The updated L2P mapping table can be used for retrieving the stored codeword in future read operations from a correct memory block.

In some examples, the controller 115 retrieves or receives the codeword from the memory block 142 corresponding to reading the stored host data in response to a data request command, for example, issued by the host system 120. For example, the controller 115 can retrieve the codeword from the memory device 130 using a NAND read operation in response to the data request command.

In some examples, the memory device 130 or 140 can perform read operations, such as hard reads (1H) to provide hard data, which includes a combination of hard bits. A “hard bit” in this context is a binary read of data where each bit is read and immediately interpreted as either a “0” or a “1”, based on a fixed threshold, a Hard Read Position (HRP) threshold, which is based on a distribution of voltage thresholds of the memory device. For example, in NAND flash memory, a voltage level above the HRP might be interpreted as “0”, and below the HRP as “1”. The hard data corresponds to a read version of the stored data in the memory block 142.

For example, the controller 115 issues a read command to the local media controller 135 to execute one or more operations on the memory cells 146 to read the stored codeword. The controller 115 sets a specific read voltage from a set of read voltages, which the local media controller 135 applies to the memory cells 146 and/or 148. The controller 115 selects and configures the local media controller 135 to apply the read voltage. The controller 115 instructs the local media controller 135 to generate and apply each read voltage to the wordline associated with the memory cells 146. This process determines the codeword stored in the cells 146 by evaluating a cell's response to the applied read voltages in response to the read command. The set of read voltages covers all possible state-specific voltage ranges corresponding to the different logical states that could be stored in the cells 146.

The set of read voltages defines a read voltage window, which includes read voltages at which one or more of the memory cells 146 may conduct. A state-specific read voltage range refers to the specific group of read voltages where the memory cells 146 and/or 148 become conductive, indicating a particular logical state (e.g., “00,” “01,” “10,” or “11”). Each logical state in a multi-level memory cell (MLC, TLC, QLC, PLC, etc.) is associated with a unique range of read voltages that allow the memory controller to determine whether the cell is storing that state. These voltage ranges are used during read operations to accurately interpret the stored data by evaluating the cell's conduction behavior across the state-specific read voltage range.

The set of read voltages can include a sequence of read voltages that can be applied to the memory cells 146. Each read voltage of the set of read voltages that is applied by the local media controller 135 can progressively increase from a minimum to a maximum read voltage level at a (predefined) voltage step size, each probing different potential charge states stored at the memory cells 146. A progressive increase in read voltages that are applied in discrete increments is known as a voltage step size, which defines a voltage difference between consecutive read levels that are applied to the memory cells 146 and/or 148. In some instances, wordline drivers can be activated by the local media controller 135 by causing a control voltage to be applied to gates of the cells 146 in that wordline, placing the memory cells 146 into a “ready” read state (e.g., ready for reading)

Each memory cell's ability to conduct depends on a charge level stored in that cell. If the charge level in a cell of the memory cells 146 and/or 148 is above an applied read voltage, the cell will conduct; otherwise, the cell will not. For example, if the cell conducts this indicates that a cell's voltage threshold is lower than or equal to an applied read voltage, meaning the cell represents a specific logic state. For higher-order cells (MLC, TLC, etc.), multiple read voltages can be applied sequentially to determine a logic state (e.g., whether the cell represents “00”, “01”, “10”, or “11” in an MLC) being stored in such cell types.

As each read voltage of the set of read voltages is applied by the local media controller 135 to the cells 146, one or more sense amplifiers connected to one or more bit lines connected to the memory cells 146 can detect whether current flows through one or more cells of the cells 146 at that applied read voltage. The detected current can be provided to the local media controller 135 corresponding to detecting a stored logical state at the one or more cells of the cells 146. In some examples, the set of read voltages are HRP thresholds that are applied to the wordline and thus the read data from the memory device 130 or 140 corresponds to the hard data (the codeword).

For example, if a cell's charge allows the cell to exceed the HRP threshold (e.g., a lower threshold state), the cell conducts current, and the one or more sense amplifiers detect this, and the local media controller 135 interprets the logical state as a “1”. Alternatively, if a cell's charge does not allow the cell to exceed the HRP threshold (e.g., a higher threshold state), the cell does not conduct current, and the one or more sense amplifiers detects no current, and the local media controller 135 interprets the logical state as a “0”.

Thus, when a cell conducts in response to an applied read voltage, a current flows through the bitline connected to that cell. The local media controller 135 monitors a current flowing through each bitline. Based on whether or not current flows (e.g., whether the cell conducts), the local media controller 135 determines a logic state being stored at each cell of the cells 146. The local media controller 135 can read all logical states being stored at the memory cells 146 that correspond to one or more bits (logical states) of the codeword. Thus, the local media controller 135 can read the memory cells 146 to read bits of the codeword.

The local media controller 135 assembles the read bits into the codeword. The codeword is then transmitted by the local media controller 135 back to the controller 115, which may further process the codeword, such as by applying error correction if necessary, and/or extracting the embedded data corresponding to the host data. The controller 115 can communicate the extracted host data back to the host system 120 to satisfy the data request command (provide requested data).

In some examples, the host system 120 issues an erase command to execute an erase process to remove the host data from the memory device 130, which can be stored as one or more codewords across the one or more memory blocks 142-144. The erase command can include a secure erase command, a sanitize erase command, or a NVM format command. Upon receiving the erase command, the controller 115 issues a block erase command to the local media controller 135 to erase the stored host data by erasing each block at which the host data is stored as the one or more codewords.

Depending on a type of erase command, the block erase operation can include a cryptographic erase, which invalidates encryption keys and renders the host data inaccessible, a traditional block erase, which physically resets the memory cells of each block, or an overwrite erase, which overwrites the memory blocks with random data to ensure no trace of the original host data remains. The controller 115 can coordinate the erasure of host data stored across one or more memory blocks 142-144 based on the erase command from the host system 120.

For instance, upon receiving the erase command, the controller 115 translates the erase command into a low-level erase command (the block erase command) that is compatible with the memory device 130, which includes the memory blocks 142 to initiate the erase process. The controller 115 identifies a physical location of the block 142 using the L2P mapping table in response to the erase command. Once a target block is identified (the block 142), the controller 115 communicates with the local media controller 135, which manages operations on the memory cells 146 of the block 142.

For example, the local media controller 135 erases the host data stored as the one or more codewords in the memory cells 146 by applying a high erase voltage to the wordlines associated with the memory cells 146 in the block 142. This high voltage effectively resets charge levels of the memory cells 146, returning the memory cells 146 to an unprogrammed state, meaning stored data (the one or more codewords) are erased. The erase process removes data stored across pages of the memory block 142, rendering the block 142 ready for future write operations. Once the erase is complete, the local media controller 135 confirms the operation to the controller 115, which updates the L2P mapping table to reflect that the block 142 is now free.

The controller 115 continuously monitors a health of memory blocks, such as blocks 142-144, to detect issues (a failure) that may compromise a reliability of these blocks. For example, the controller 115 can utilize a memory block manager 108 to track the health of memory blocks 142-144 in the memory device 130 or memory blocks in the memory device 140. The memory block manager 108 evaluates factors that can impact block reliability, including error rates, P/E cycle counts, and occurrence of uncorrectable errors. In some examples, the memory block manager 108 monitors for a program status fail or erase status fail. A program status fail occurs when the controller 115 is unable to successfully write data to a memory block, indicating that the block has become unreliable for future program operations. An erase status fail occurs when the memory block cannot be successfully erased, indicating that the memory block can no longer be reliably reused for future operations. These failures indicate that the block has degraded and can no longer be relied upon for proper functioning.

In some examples, the memory block manager 108 determines that the block 142 is a bad block in response to detecting a block failure. The determination can be made based on one or more factors, such as a program status fail (e.g., a NAND program status fail), an erase status fail, a high frequency of uncorrectable errors, excessive P/E cycles, and/or a significant increase in read disturb or retention errors. For instance, if the memory block manager 108 detects that block 142 has exceeded a predefined threshold of P/E cycles and is also producing an increasing number of read errors that cannot be corrected by the ECC, the block 142 is flagged as a bad block corresponding to detecting a block failure. In some examples, if the memory block manager 108 detects a program status fail or erase status fail, the block 142 is flagged as a bad block because these failures indicate that the block 142 can no longer be reliably used for storing or erasing data.

For example, the memory block manager 108 marks in a BBT that the block 142 is a bad block in response to detecting the block failure for this block. The BBT can be stored in the local memory 119. The BBT tracks which memory blocks of the memory devices 130 and/or 140 should not be used in future read, write, and/or erase operations. Once the block 142 has been marked bad in the BBT, the controller 115 (the memory block manager 108) can update the L2P mapping table so that the block 142 is no longer a valid physical location for storing host data. Any logical addresses previously mapped to the block 142 are either invalidated or redirected to a new, healthy block, such as a replacement block (also known as a spare block) of the memory device 130.

In some examples, in response to the memory block manager 108 identifying that block 142 is a bad block (corresponding to detecting the block failure), the memory block manager 108 can initiate a block retirement process to retire the block 142 to prevent further use of this block. In response to detecting the block failure, the memory block manager 108 can initiate a data loss curtailment process. For example, the memory block manager 108 can implement a data recovery process to recover data (e.g., the one or more codewords) from the block 142 prior to retirement. In some instances, before retiring the block 142, the memory block manager 108 attempts to recover any host data stored in the block 142, such as the one or more codewords in the memory cells 146. This data recovery process involves reading the stored data (the one or more codewords from the memory cells 146) despite the block 142 being in a degraded state (or bad block state).

The controller 115 issues a read command to the local media controller 135 to retrieve charge states stored in each cell of the cells 146, translating the stored charge states into the corresponding logical states (e.g., 0s and 1s) to provide recovered data. The recovered data can include the one or more codewords. The recovered data is temporarily stored in a buffer or cache. The memory block manager 108 (or the controller 115) initiates a reprogramming process at the memory device 130 to transfer the recovered data to a healthy block (a spare memory block on the memory device 130). The controller 115, in coordination with the local media controller 135, selects an available replacement block from spare blocks in the memory device 130.

For example, the local media controller 135 programs the recovered data by writing the recovered data to the replacement block. After the recovered data is successfully written to the replacement block, the memory block manager 108 updates the LP2 mapping table to reflect a new physical location of the migrated data (the replacement block). Thus, once the recovered data has been successfully moved, the memory block manager 108 marks the block 142 as retired and this block can be referred to as a retired block.

In some examples, during the block retirement process, the memory block 142 is erased to erase any host data stored at the memory block 142. In some examples, the host system 120 provides the erase command to the controller 115 to erase the host data. The erase command can indicate a request to erase host data that is being stored on the memory devices 130 and/or 140. Thus, in some examples, the host data can be stored on one or more memory blocks, such as the memory blocks 142-144.

The controller 115 uses the memory block manager 108 to determine whether the host data (that the host system 120 would like to erase) is stored on retired memory blocks, also known as grown bad blocks (GBB). A GBB refers to a memory block that has become unreliable over time due to wear and tear (e.g., excessive P/E cycles, uncorrectable errors, program status fail, or erase status fail).

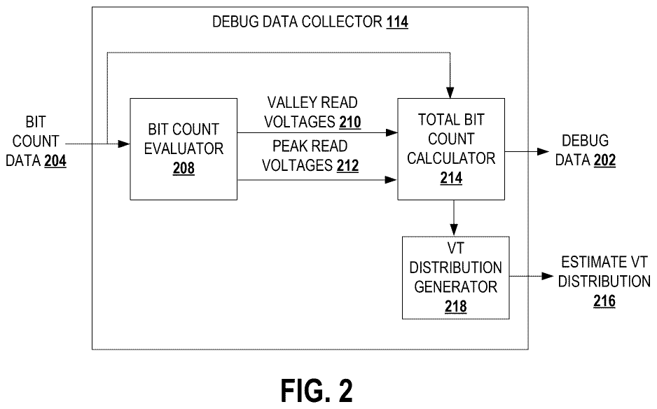

In some examples, the controller 115 is configured with a debug data collector 114. In the example of FIG. 1, the debug data collector 114 is implemented as part of the error corrector 113, in other examples, the debug data collector 114 can be implemented as a stand-alone module, or as part of the memory block manager 108. FIG. 2 illustrates an example of the debug data collector 114 of FIG. 1. The debug data collector 114 can be implemented using one or more modules, shown in block form in the drawings. The one or more modules can be in software or hardware form, or a combination thereof. In some examples, one or more functions of the debug data collector 114 can be implemented as machine readable instructions for execution by the controller 115, as shown in FIG. 1.

The debug data collector 114 is configured/programmed to provide debug data 202, as shown in FIG. 2. The debug data collector 114 can output the debug data 202 characterizing peak and valley distribution information for the memory cells 146-148 based on bit count data 204. The debug data 202 can be stored in the local memory 119, for example, for a debugging process, such as described herein. For example, the debug data 202 can be used by engineers during the debugging process for identifying a root cause of failure of a bad block (e.g., the block 142). The debug data 202 can include estimate peak and valley distribution information that can be used for generating an estimate VT distribution 216 for the memory cells 146 and/or 148. In some examples, the controller 115 can provide the estimate VT distribution 216 according to one or more examples herein.

For example, the controller 115 can execute the debug data collector 114 in response to detecting a memory failure condition, such as the block failure. The block failure can include, for example, the program status fail, the erase status fail, uncorrectable read or write errors, excessive P/E cycles, and/or other issues like read disturb or retention errors. In other examples, the debug data collector 114 can be invoked in response to the controller 115 receiving the erase command from the host system 120. In such cases, if the memory block manager 108 detects that the memory device 130 contains a GBB (the bad block, such as block 142), the debug data collector 114 collects failure data (the estimate peak and valley distribution information) to provide the debug data 202. After the debug data collector 114 provides the debug data 202, the controller 115 instructs (or controls) the local media controller 115 to perform an erase operation on the GBB (e.g., the block 142) and any other valid blocks (non-retired blocks) that store the user data (host data) being requested by the host system 120 to be removed/deleted according to one or more examples herein.

In some examples, the debug data collector 114 can be triggered (executed) either by a firmware of the controller 115 (e.g., the memory block manager 108 in response to detecting the memory failure condition) or in response to a host system command (e.g., the erase command from the host system 120). By executing the debug data collector 114 in response to detecting the memory failure condition or the erase command, the controller 115 is able to gather and store failure data with minimal performance impact to provide the debug data 202. The debug data 202 can then be used for determining a root cause of failure of the GBB (e.g., the bad block, such as the block 142).

For example, after the debug data collector 114 is executed, the debug data collector 114 instructs the controller 115 to implement a debug data collection process. During the debug data collection process, the controller 115 instructs the local media controller 135 to apply the set of read voltages to the memory cells 146 to probe the memory cells 146-148. In some examples, during the debug data collection process, the controller 115 instructs the local media controller 135 to apply the set of read voltages (or a different set of read voltages) to the memory cells 148. The debug data collector 114 can specify a voltage step size between read voltages of the set of read voltages that are applied by the local media controller 135 to the memory cells 146. As an example, the voltage step size can be in a range of 10-50 millivolts (mV). The voltage step size can be based on a desired accuracy for detecting voltage thresholds of the memory cells 146. The set of read voltages is used to sweep across a range of all possible voltage thresholds of the memory cells 146.

For example, during the debug data collection process, the controller 115 can issue a bit count command to the local media controller 135 to initiate a bit count operation. The local media controller 135 includes a bit counter 112 for performing the bit count operation. A number of bit count operations implemented by the local media controller 135 can be determined by a number of read voltages of the set of read voltages that are to be applied. During each bit count operation, a specific read voltage of the set of read voltages is applied to the memory cells 146. A complete operation that involves performing multiple bit count operations across the entire set of read voltages can be referred to as a bit count sweep operation. The bit count operation is used to determine a number of cells of the cells 146, in some instances, the cells 148, that have a zero at a specific read voltage for a bit position. A bit position refers to which bit within a single or multi-bit value stored by a respective one of single or multi-level memory cells that are being read. In multi-level cells, different bits correspond to different charge levels, and the bit count operation can be used to read one bit position at a time (e.g., least significant bit (LSB), middle bit, or most significant bit (MSB)).

During each bit count operation (process), the bit counter 112 counts how many memory cells of the memory cells 146, at a given applied read voltage, have a voltage threshold below that read voltage, causing these cells to be interpreted as storing logical 0s. A number of cells of the memory cells 146 and/or 148 that do not respond at a read voltage in a bit count operation is representative of cells that store a zero at a particular bit position for that specific read voltage. Thus, when the local media controller 135 applies a specific read voltage, the bit counter 112 counts how many cells of the cells 146 do not conduct, which is interpreted as storing zero bits for a current bit position being read. For example, if the read voltage is designed to target a LSB (a least significant bit), the bit count operation measures how many cells store a zero at an LSB across the memory cells 146 at that read voltage. The local media controller 135 repeats the bit count operation across different read voltages of the set of read voltages for the cells 146.

In examples in which the memory cells 146 of the block 142 are SLCs, referred to herein as a first example, each of the cells 146 can store 1 bit of data, with two possible states: a cell with a voltage threshold below a certain level represents a logical 0, while a cell with a voltage threshold above that level represents a logical 1. In the first example, the read voltage level is set to 500 mV. When the bit count command is issued, the local media controller 135 applies this read level and counts how many cells have a voltage threshold lower than 500 mV corresponding to conducting. These cells will be interpreted as storing zero bits. For example, if the bit counter 112 counts 130,000 bits that register as zero at this read level, this information is recorded by the bit counter 112.

In a second example, memory cells of the block 142 are multi-level cells, such as TLCs, and each cell stores 3 bits of data, allowing for 8 possible data states ranging from 000 to 111. Each of these data states corresponds to a different read voltage range. In the second example, the read voltage is set to 500 mV. In the second example, the bit counter 112 counts an LSB for cells of the cells 146 with a voltage threshold below 500 mV, meaning the cells in states where the LSB is 0 are counted. For example, if 120,000 zero bits are counted at this read level, this would indicate that 120,000 TLC cells have a LSB set to 0. The read level can be incrementally increased to check for other bit positions within the 3-bit value stored in each TLC cell (e.g., middle or upper page), depending on an applied read voltage.

Accordingly, the bit count operation is repeated across the set of read voltages (the read voltage window) by adjusting the applied read voltage to a next read level in the set of read voltages. This continues until all the read voltages in the set of read voltages have been applied to gather 0 bit count information for the memory cells 146.

In response to the bit count operation, the local media controller 135 can provide the controller 115 with bit count data 204, as shown in FIG. 2. In some examples, the local media controller 135 can provide the controller 115 with the bit count data 204 in response to completing the bit count sweep operation on the memory cells 146. In other examples, the local media controller 135 provides bit counts in response to each bit count operation to the controller 115 and the controller 115 stores this information as bit count data 204 in the local memory 119. The bit count data 204 can be used, in some instances, by the controller 115 to approximate peaks and valleys of a VT distribution. The local media controller 135 can provide bit count data 204 for each page type that can be stored in the memory block 142. Thus, in some examples, the bit count data 204 can include bit counts for a target, a set of target pages, or all page types that can be implemented as part of the memory block 142.

The bit count data 204 represents a number of memory cells of the memory cells 146 that store a zero bit (at a bit position) at a respective applied read voltage. Thus, the bit count data 204 indicates a number of memory cells of the memory cells 146 with zero bits at an applied read voltage of the set of read voltages. The bit count data 204 illustrates a number of bits (at each bit position) across the cells 146 that are counted as zero across all applied read voltages of the set of read voltages.

In a multi-level cell (e.g., TLC, MLC), each bit position can be read at different voltage levels, and the bit count data 204 can reflect how many cells are storing zeros at each bit position for a corresponding read level. As described herein, the bit count data 204 can be determined using multiple bit count operations. During each bit count operation, the local media controller 135 applies a specific read voltage to the memory cells 146 and/or 148 and determines how many of these cells do not conduct (because a respective voltage threshold for these cells is higher than the applied read voltage) to interpret these cells as storing a zero.

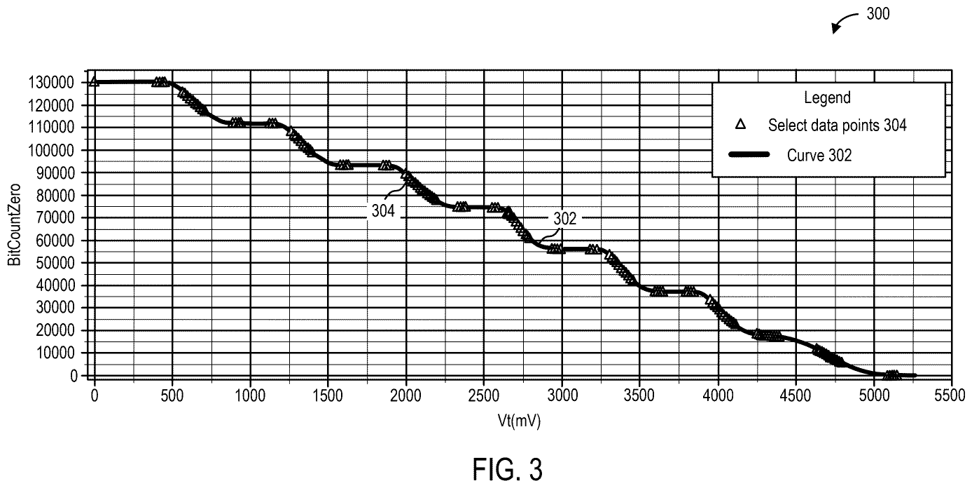

In some examples, the controller 115 can store the bit count data 204 in the local memory 119 as a bit count graph 300, as shown in FIG. 3. The bit count graph 300 plots zero bit count values as a function of read voltages, in millivolts (mV) for the set of read voltages that had been applied to the memory cells 146. The zero bit count values refer to a number of bits that remain in the zero state (e.g., bit positions that had a logical 0) when a specific read voltage was applied. The graph 300 includes a zero bit count distribution curve 302. The curve 302 represents a relationship between the set of read voltages that was applied to the cells 146 and a number of zero bits stored at one or more cells of the cells 146 at each read level. The curve 302 is composed of data points. Each data point on the curve 302 can represent a specific read voltage and a corresponding zero bit count value.

For example, the controller 115 can quantify how the zero bit count values change across a range of applied read voltages to determine a zero bit count rate of change for each read voltage. In some examples, the controller 115 computes a slope value for each read voltage corresponding to the zero bit count rate of change. The slope represents a rate at which zero bits transition to one bits across the set of applied read voltages. A negative slope indicates a drop in zero bit count in FIG. 3, corresponding to a transition of bits from zero to one across the set of applied read voltages. Thus, there is a greater shift in a number of cells (e.g., at read positions) of the cells 146 being read as “0” to “1” based on the applied read voltage. A positive or zero slope indicates either an increase or no change in zero bit count, where fewer bits transition from zero to one. This means there is a lower shift in a number of cells (e.g., at read positions) of the cells 146 being read as “0” to “1” based on the applied read voltage.

Each zero bit count rate of change (slope) value computed for each read voltage, as shown in FIG. 3, can be compared by the controller 115 to a first threshold to identify read voltages with slope values that are greater than or equal to the first threshold. The read voltages that exceed the first threshold can be referred to as peak read voltages 212, where a sharp drop in zero bit count occurs, indicating a significant number of bits transitioning to a zero corresponding to a significant number of bits transitioning to a one in FIG. 3. This is because at these read levels, a rate of bit transitions from zero to one is high (the curve 302 has a larger negative slope, as shown in FIG. 3) and there is a sharp drop in zero bit count values.

A peak read voltage refers to a read voltage of a set of read voltages of the bit count graph 300 (the bit count data) at which the rate of change in zero bit count is significantly high, indicating that a large number of bits are transitioning from zero to one. This corresponds to a sharp drop in the bit count curve, where the number of zero bits decreases rapidly over a range of read voltages, as shown in FIG. 3. Peak read voltages 212 correspond to read levels of a VT distribution where a greatest amount of memory cells of the cells 146 store particular logical states. Thus, the peak read voltages 212 are read voltages associated with one or more peak portions of each peak of each distribution portion of the VT distribution. The peak read voltages 212 as described herein can be used in providing the estimate VT distribution 216, as shown in FIG. 2.

In some examples, the controller 115 can compare each zero bit count rate of change value to a second threshold (which is less than the first threshold) to identify valley read voltages 210. In some examples, the first and second predefined thresholds are zero bit count rate change thresholds that can be used to classify the read voltages into peak and valley read voltages. A valley read voltage is a read voltage at which the rate of change in zero bit count is minimal or close to zero, indicating that few or no bits are transitioning from zero to one (e.g., cells being read as storing a particular bit position a 0). This corresponds to a flat or nearly flat region in the curve 302, where the number of zero bits remains relatively stable over a range of read voltages.

Valley read voltages 210 are similar to the read voltages located in a valley between distribution portions, thus in a region where fewer cells are read as 0 s at corresponding read voltages. Thus, the valley read voltages 210 can correspond to read voltages associated with valley portions of distribution portions of the VT distribution representing a respective logical state that can be stored in the memory cells 146. In some examples, the valley read voltage 210 can correspond to read voltages associated with one or more tails of the distribution portions of the VT distribution. The valley read voltages 210 correspond to areas where there is a low rate of change in transition of bits, typically located between peaks (indicating major logical transitions) or in the tails of the distribution (where fewer cells are in transition). Transition of bits refers to a point at which a group of memory cells shifts from being interpreted as “0”s to being interpreted as “1”s (or vice versa) as the read voltage crosses certain thresholds. Thus, a low rate of change in bit transitions indicates that at certain voltages (the valley read voltages 210), a number of memory cells switching from being read as “0” to being read as “1” is minimal or close to zero. In this case, a distribution curve portions flattens out, indicating a stable number of cells remaining in the same logical state (“0” or “1”) as the applied voltage changes.

In the example of FIG. 3, data points with read voltages corresponding to the valley and peak read voltages 210 and 212 are identified with triangles as 304 and are referred to as select data points 304 (or candidate data points 304). The candidate data points 304 represents where significant changes in zero bit count occur, either showing a sharp drop (peaks) or little to no change (valleys). The valley and peak read voltages 210 and 212 can include a number of valley and peak read voltage groups, as shown in FIG. 3. Each group of peak read voltages corresponds to a range of read voltages where a large number of memory cells transition from zero to one, indicating an elevated level of activity. These groups form because different logical states of memory cells have different voltage thresholds.

When the read voltage reaches or exceeds the VT of a particular group of cells, a significant number of bits transition, forming a peak. Similarly, groups of valley read voltages represent regions where there is minimal change in zero bit count value, corresponding to areas between logical states where fewer memory cells have voltage thresholds close to the applied read voltage. These valleys reflect low activity, where fewer bits transition because the voltage thresholds of one or more of cells 146 are not within the applied read voltage range.

The debug data collector 114 can include a total bit count calculator 214 (for simplicity calculator 214). The calculator 214 can determine for each of the valley and peak read voltages 210-212 from the bit count data 204 a bit count value. A bit count (or bit count value) represents a number of memory cells that store a respective logical state at an applied read voltage.

In some examples, the calculator 214 computes the bit count based on a total number of memory cells (e.g., a number of the memory cells 146) and a number of memory cells that had a zero at a specified read voltage (that is number of cells had a zero). The number of cells that had a zero at a specified peak or valley read voltage corresponds to a bit zero count value at that voltage. This value represents the number of memory cells that remain in a zero state and can be retrieved from the bit count data 204 for the specific read voltage. For each peak and/or valley read voltage, the bit count zero value is used to calculate the total bit count, reflecting the number of cells that have transitioned from zero to one.

The debug data collector 114 provides the debug data 202 based on the valley and peak read voltages 210 and 212 and a respective calculated bit count, which corresponds to valley and peak distribution information. The debug data 202 can be stored in the local memory 119 of the controller 115, where the debug data 202 can be accessed to provide the estimate VT distribution 216. In some instances, the debug data collector 114 can provide the estimate VT distribution 216 for the memory cells 146. In some examples, the debug data collector 114 further includes a VT distribution generator 218 (referred to as “generator 218”).

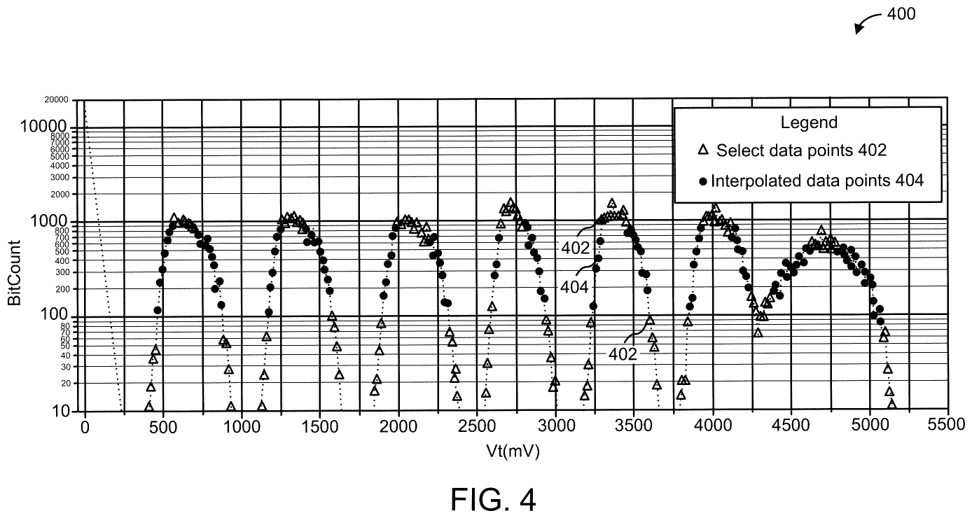

The generator 218 receives the debug data 202 to compute the estimate VT distribution 216. The estimate VT distribution 216 can be stored in the local memory 119, in some examples, as a VT distribution graph, such as a VT distribution graph 400, as shown in FIG. 4. The estimate VT distribution 216 can occupy less memory space in contrast to a traditional computed VT distribution. This is because the estimate VT distribution 216 is calculated using selected peak and valley read voltages (e.g., significant points of change in the distribution), rather than storing the entire distribution with every possible voltage step.

FIG. 4 is an example of a graph 400 that includes the estimate VT distribution 216 that can be computed by the generator 218. The graph 400 plots bit count values as a function of read voltages, in mV, for the set of read voltages that had been applied to the memory cells 146. The bit count values refers to a number of memory cells that conducted at a particular read voltage of the set of read voltages. In the example of FIG. 4, data points having read voltages corresponding to the valley and peak read voltages 210-212 (the candidate data points 304) are identified with triangles 402 similar to in FIG. 3.

The generator 218 can construct the estimate VT distribution 216 (as shown in FIG. 4) using the valley and peak read voltages 210-212 and computed bit count values for these read voltages by the calculator 214. In some examples, the generator 218 can interpolate data points between the valley and peak read voltages 210-212 to provide the estimated VT distribution 216, as shown in FIG. 4. The interpolated data points are identified with filled circles 404 in the example of FIG. 4. Once constructed, the estimated VT distribution 216 can be used for debugging of a bad memory block (e.g., the block 142) according to one or more examples herein.

Accordingly, by configuring the memory sub-system 110 with the debug data collector 114, valley and peak distribution information corresponding to the debug data 202, can be collected while the memory sub-system 110 is in use with minimal impact on a performance of the memory sub-system 110. The minimal performance impact arises because the bit count command records only a number of zero bits at each applied read voltage, rather than requiring a full read operation across the memory device 130. The debug data 202 is stored in the local memory 119 and can aid in the debugging process, as described herein, even after the memory device 130 is formatted.

Using the bit count command to record the number of zero bits reduces a need for large data transfers typically required during normal read operations (e.g., NAND read operations), thereby significantly reducing a time required to collect VT distribution information. This approach reduces the need for large data transfers typically required during normal read operations, such as reading entire codewords or pages of data. Instead, the local media controller 135 only reports the zero-bit count for each applied read voltage, minimizing data transfer between the memory sub-system controller 115 and the local media controller 135.

As a result, a time required to collect VT distribution information is significantly reduced, since the debug data collector 114 can retrieve essential bit count data without needing to perform a full data read or transfer large amounts of read-back data from the memory cells. In addition, the collected VT distribution information can be determined prior to an erase operation, allowing for data recovery or further debugging to be conducted before host data is permanently removed from the memory device 130 or 140.

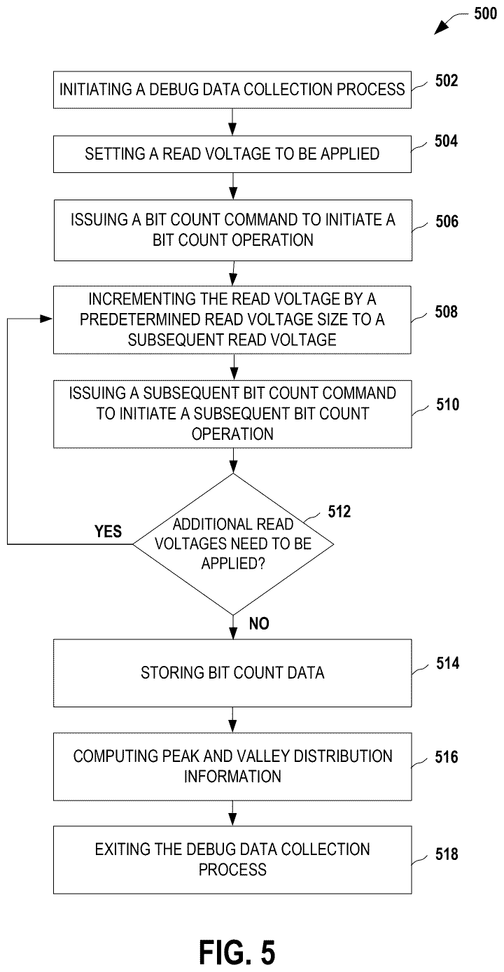

FIG. 5 illustrates a flowchart of an example method 500 for collecting valley and peak distribution information for VT distribution approximation for a memory device, such as the memory device 130 or 140 according to one or more examples of the present disclosure. The method 500 can be implemented, for example, by the controller 115 of the memory sub-system 110.

At block 502, the controller 115 initiates a debug data collection process to collect the valley and peak distribution information. At block 504, the controller 115 sets a read voltage of a set of read voltages to be applied by the local media controller 135 to the memory cells 146 and/or 148 in response to initiating the debug data collection process. For example, the controller 115 selects and configures the local media controller 135 for applying the read voltage corresponding to setting the read voltage at the local media controller 135. At block 506, the controller 115 issues a bit count command to the local media controller 135 to initiate a bit count operation to apply the read voltage to the memory cells 146 and/or 148 to determine a number of memory cells of the memory cells 146 and/or 148 storing a zero bit at the applied read voltage.

At block 508, the controller 115 increments the read voltage by a predetermined read voltage size to a subsequent read voltage of the set of read voltage that is to be applied by the local media controller 135 to the memory cells 146 and/or 148. At block 510, the controller 115 issues a subsequent bit count command to the local media controller 135 to initiate a subsequent bit count operation to apply the subsequent read voltage to the memory cells 146 and/or 148 to determine a number of memory cells of the memory cells 146 and/or 148 storing the zero bit at the subsequent applied read voltage.

At block 512, the controller 115 makes a determination if additional read voltages of the set of read voltages need to be applied to collect additional zero bits. The method 500 can proceed from block 512 to block 508 (shown as a “YES” in FIG. 5) in response to determining that additional read voltages of the set of read voltages remain to be applied. The process of incrementing the read voltage and performing bit count operations (blocks 508-510) is repeated until each read voltage in the set of read voltages has been applied to produce the bit count data 204. Accordingly, at block 512, the method 500 proceeds to block 514 from block 512 (shown as a “NO” in FIG. 5) in response to determining that the set of read voltages have been applied.

At block 514, the bit count data 204 representative of the number of memory cells of the memory cells 146 and/or 148 storing the zero bit across all of the applied read voltages of the set of read voltages is stored by the controller 115 in the local memory 119. At block 516, the controller 115 can compute the peak and valley distribution information to provide the debug data 202 based on the bit count data 204 according to one or more examples herein. In some examples, at block 516, the controller 115 stores the computed debug data 202 in the local memory 119 in response to outputting the debug data 202. At block 518, the controller 115 exits the debug data collection process in response to storing the computed debug data 202 in the local memory 119.

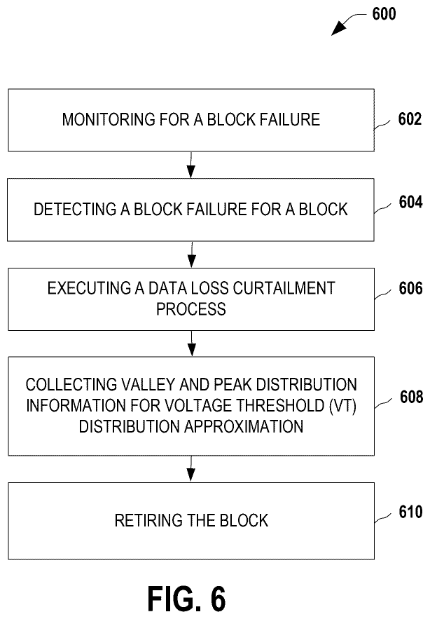

FIG. 6 is an example of a method 600 for retiring a bad block, such as the block 142 of the memory device 130 or 140 according to one or more examples of the present disclosure. The method 600 can be implemented, for example, by the controller 115 of the memory sub-system 110.

At block 602, the controller 115 monitors the memory device 130 or 140 for a block failure according to one or more examples as described herein. At block 604, the controller 115 detects the block failure for the block 142. At block 606, the controller 115 can execute a data loss curtailment process to respond to the block failure. The data loss curtailment process can include recovering the stored data at the block 142 or reprogramming the stored data into another block (e.g., a replacement or spare block) according to one or more examples herein. At block 608, valley and peak distribution information for VT distribution approximation can be collected according to the examples herein. For example, the method 500 can be implemented at block 608 to compute the valley and peak distribution information to provide the debug data 202 of FIG. 2. At block 610, the block 142 can be retired according to a block retirement process, such as described herein.

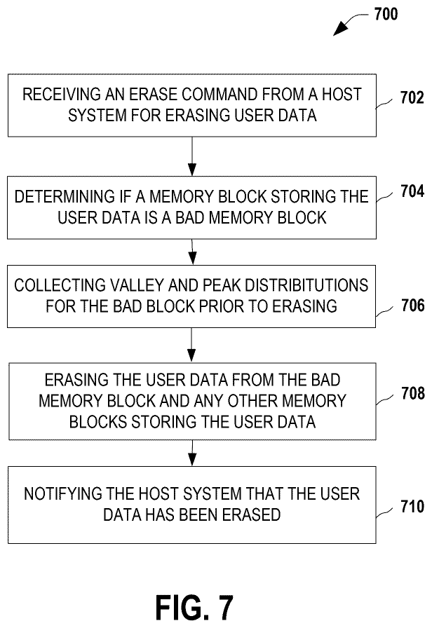

FIG. 7 is an example of a method 700 for erasing user data stored at one or more blocks, such as the block 142-144 of the memory device 130 or 140 according to one or more examples of the present disclosure. The method 700 can be implemented, for example, by the controller 115 of the memory sub-system 110.

At block 702, the controller 115 receives an erase command from the host system 120 for erasing (removing) the user data. The user data can be stored as one or more codewords at the one or more blocks 142-144. In the example of FIG. 7, the block 142 is a bad block that has been retired according to one or more examples. At block 704, the controller 115 determines if the user data is stored on any retired blocks, such as the block 142. At block 704, in some instances, the controller 115 determines the user data is stored at block 142.

At block 706, valley and peak distribution information for VT distribution approximation can be collected according to the examples herein. For example, the method 500 can be implemented at block 706 to compute the valley and peak distribution information to provide the debug data 202 of FIG. 2. At block 708, the controller 115 can erase the user data from the block 142 and any other blocks, such as the memory block 144 of the memory device 130 in response to collecting the valley and peak distribution information. In some examples, at block 710, the method 700 includes notifying the host system 120 that the user data has been erased. By collecting valley and peak distribution information prior to data erasure allows for effective debugging and root cause analysis of memory failures, which would otherwise be lost during an erase operation.

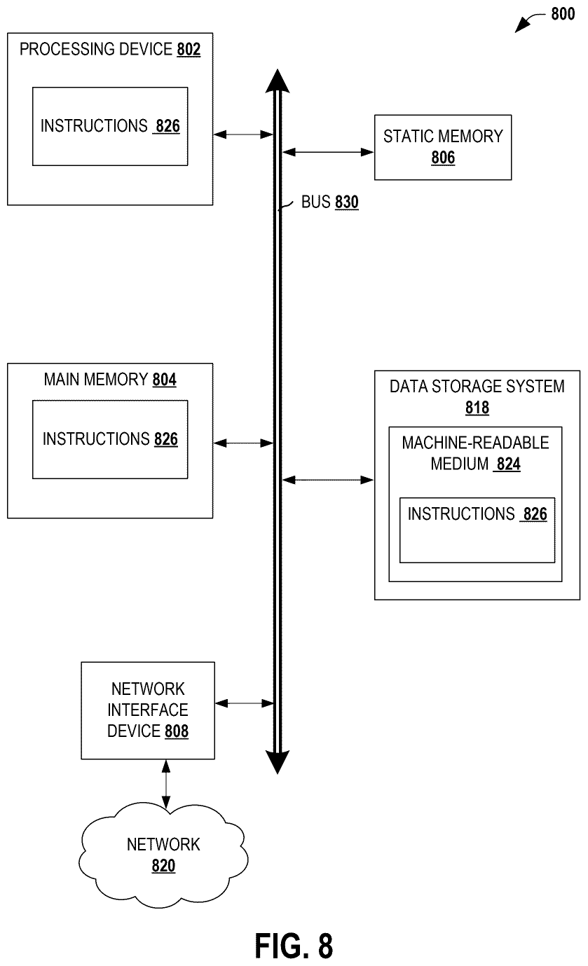

FIG. 8 illustrates an example machine of a computer system 800 (a machine) within which a set of instructions, for causing the machine to perform any one or more of the methodologies discussed herein, can be executed. In some examples, the computer system 800 corresponds to a host system (e.g., the host system 120 of FIG. 1) that includes, is coupled to, or utilizes a memory sub-system (e.g., the memory sub-system 110 of FIG. 1) or is used to perform the operations of a controller (e.g., to execute an operating system to perform operations corresponding to error corrector 113 of FIG. 1 and/or the debug data collector 114). In other examples, the machine is connected (e.g., networked) to other machines in a LAN, an intranet, an extranet and/or the Internet. In various examples, the machine operates in the capacity of a server or a client machine in client-server network environment, as a peer machine in a peer-to-peer (or distributed) network environment or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge or any machine capable of executing a set of instructions (sequential or otherwise) that specify actions to be taken by that machine. In other examples, the machine may be a computer within an automotive, a data center, a smart factory or other industrial application. Further, while a single machine is illustrated, the term “machine” shall also be taken to include any collection of machines that individually or jointly execute a set (or multiple sets) of instructions to perform the methodologies discussed herein.

The example computer system 800 includes a processing device 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM) or other non-transitory computer-readable media) and a data storage system 818, which communicate with each other via a bus 830.

The processing device 802 represents one or more general-purpose processing devices such as a microprocessor, a central processing unit, etc. More particularly, the processing device 802 can be a complex instruction set computing (CISC) microprocessor, reduced instruction set computing (RISC) microprocessor, very long instruction word (VLIW) microprocessor or a processor implementing other instruction sets or processors implementing a combination of instruction sets. In some examples, the processing device 802 is implemented with a special-purpose processing devices such as an application specific integrated circuit (ASIC), a field programmable gate array (FPGA), a digital signal processor (DSP), network processor, etc. The processing device 802 is configured to execute instructions 826 for performing the operations discussed herein. In some examples, the computer system 800 includes a network interface device 808 to communicate over the network 820.

The data storage system 818 includes a machine-readable storage medium 824 (also known as a computer-readable medium) that store sets of instructions 826 or software for executing the methodologies and/or functions described herein. The machine-readable storage medium 824 is a non-transitory medium. The instructions 826 can also reside, completely or at least partially, within the main memory 804 and/or within the processing device 802 during execution thereof by the computer system 800, the main memory 804 and the processing device 802 also constituting machine-readable storage media. The machine-readable storage medium 824, data storage system 818 and/or main memory 804 can correspond to the memory sub-system 110 of FIG. 1. Accordingly, the machine-readable storage medium 824, the data storage system 818 and/or the main memory 804 are examples of non-transitory computer-readable media.

In some examples, the instructions 826 include instructions to implement functionality corresponding to the error corrector 113 of FIG. 1. While the machine-readable storage medium 824 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared and otherwise manipulated. It has proven convenient at times, principally for reasons of common usage, to refer to these signals as bits, values, elements, symbols, characters, terms, numbers, etc.

It is noted, however, that all of these and similar terms are to be associated with the appropriate physical quantities and are merely convenient labels applied to these quantities. This description can refer to the action and processes of a computer system, or similar electronic computing device, which manipulates and transforms data represented as physical (electronic) quantities within the computer system's registers and memories into other data similarly represented as physical quantities within the computer system memories or registers or other such information storage systems.

This description also relates to an apparatus for performing the operations herein. This apparatus can be specially constructed for the intended purposes or this apparatus can include a general purpose computer selectively activated or reconfigured by a computer program stored in the computer. Such a computer program can be stored in a computer readable storage medium, such as, but not limited to, any type of disk including floppy disks, optical disks, CD-ROMs, magnetic-optical disks, read-only memories (ROMs), random access memories (RAMs), EPROMs, EEPROMs, magnetic or optical cards or any type of media suitable for storing electronic instructions, each coupled to a computer system bus.

The algorithms and displays presented herein are not inherently related to any particular computer or other apparatus. Various general purpose systems can be used with programs in accordance with the descriptions herein, or it can prove convenient to construct a more specialized apparatus to perform the method. In addition, the present disclosure is not described with reference to any particular programming language. It will be appreciated that a variety of programming languages can be used to implement the teachings of the disclosure as described herein.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications and variations that fall within the scope of this application, including the appended claims. As used herein, the term “includes” means includes but not limited to, the term “including” means including but not limited to. The term “based on” means “based at least in part on”. Additionally, where the disclosure or claims recite “a,” “an,” “a first” or “another” element, or the equivalent thereof, it should be interpreted to include one or more than one such element, neither requiring nor excluding two or more such elements.

What is claimed is:

1. A method comprising:
setting, by a controller, a read voltage from a set of read voltages to be applied to memory cells of a memory device;
issuing, by the controller, a bit count command to the memory device to apply the read voltage to the memory cells to count a number of memory cells of the memory cells storing a zero bit;
repeating, by the controller, the setting and issuing operations until remaining read voltages of the set of read voltages have been applied to the memory cells to determine the number of memory cells storing the zero bit at each remaining read voltage applied to the memory cells;
receiving, by the controller, bit count data in response to the repeating operation, wherein the bit count data represents the number of memory cells of the memory cells storing the zero bit at each read voltage applied to the memory cells; and
providing, by the controller, debug data characterizing peak and valley distribution information for the memory cells based on the bit count data.

2. The method of claim 1, wherein the providing comprises evaluating, by the controller, each read voltage applied to the memory cells relative to thresholds to identify:
read voltages associated with one or more peaks of a voltage threshold (VT) distribution for the memory cells corresponding to peak read voltages; and
read voltages associated with one or more valleys of the VT distribution for the memory cells corresponding to valley read voltages.

3. The method of claim 2, further comprising providing, by the controller, an estimate of the VT distribution for the memory cells based on the valley and peak read voltages.

4. The method of claim 3, wherein the estimate VT distribution is provided prior to execution of an erase operation that erases data stored at the memory cells.

5. The method of claim 3, wherein the providing further comprises determining, by the controller, for each of the valley and peak read voltages a bit count value, the bit count value representing the number of memory cells of the memory cells that store a respective logical state of logical states at a corresponding read voltage of the set of read voltages applied to the memory cells, the estimate VT distribution being further provided based on bit count values for the valley and peak read voltages.

6. The method of claim 1, further comprising providing, by the controller, an estimate voltage threshold (VT) distribution for the memory cells based on the debug data.

7. The method of claim 1, wherein the setting, issuing, and repeating operations are implemented for a debug data collection process, and the method further comprising:
monitoring, by the controller, the memory device for a memory failure condition;
executing, by the controller, a data loss curtailment process in response to detecting the memory failure condition; and
executing, by the controller, the debug data collection process in response to executing the data curtailment process.

8. The method of claim 7, wherein the memory device includes a memory block that include the memory cells, and the memory failure condition is a block failure condition for the memory block.

9. The method of claim 8, further comprising retiring, by the controller, the memory block in response to executing the debug data collection process.

10. The method of claim 9, wherein the block failure condition comprises a program status fail and/or an erase fail status.

11. The method of claim 1, wherein the setting, issuing, and repeating operations are implemented for a debug data collection process, the memory device comprising a retired memory block that include the memory cells, and the method further comprising:
receiving, by the controller, an erase command to remove data being stored on the memory device;
determining, by the controller, that the data is stored in the retired memory block in response to receiving the erase command; and
executing, by the controller, the debug data collection process in response to determining that the data is stored in the retired memory block.

12. The method of claim 11, further comprising erasing, by the controller, the retired memory block to erase the data in response to executing the debug data collection process.

13. The method of claim 11, wherein the erase command comprises a secure erase command, a sanitize erase command or a Non-Volatile Memory (NVM) format command.

14. The method of claim 1, wherein the memory device is a Not-AND (NAND) memory device and the cells are multi-level cells.

15. A system for generating debug data for debugging a memory device comprising memory cells, the system comprising:
a processing device coupled to the memory device, the processing device to perform operations comprising:
generating the debug data characterizing peak and valley distribution information for the memory cells in response to a debug data collection process, wherein, during the debug data collection process, a first read voltage is applied to the memory cells to count a number of memory cells of the memory cells storing a zero bit at the first read voltage based on a first bit count command and a second read voltage is applied to the memory cells to count the number of memory cells storing the zero bit at the second read voltage based on a second bit count command to produce bit count data, the bit count data representing a number of memory cells of the memory cells storing the zero bit at each read voltage applied to the memory cells, and the debug data being generated based on the bit count data.

16. The system of claim 15, wherein the operations further comprising:
monitoring the memory device for a memory failure condition;
executing a data loss curtailment process in response to detecting the memory failure condition; and
executing the debug data collection process in response to executing the data loss curtailment process.

17. The system of claim 15, wherein the memory device includes a retired memory block that includes the memory cells, and the operations further comprising:
receiving an erase command to remove data being stored on the memory device;
determining that the data is stored in the retired memory block; and
executing the debug data collection process in response to determining that the data is stored in the retired memory block.

18. The system of claim 16, further comprising computing an estimate voltage threshold (VT) distribution for the memory cells based on the debug data.

19. A non-transitory computer-readable storage medium comprising instructions that, when executed by a processing device, cause the processing device to perform operations comprising:
setting a read voltage of a set of read voltages to be applied to memory cells of a memory device;
issuing a bit count command to the memory device to apply the read voltage to the memory cells to count a number of memory cells of the memory cells storing a zero bit;
repeating the setting and issuing operations until remaining read voltages of the set of read voltages have been applied to the memory cells to determine the number of memory cells storing the zero bit at each remaining read voltage applied to the memory cells;
receiving bit count data in response to the repeating operation, wherein the bit count data represents the number of memory cells of the memory cells storing the zero bit at each read voltage applied to the memory cells; and
outputting debug data characterizing peak and valley distribution information for the memory cells based on the bit count data.

20. The non-transitory computer-readable storage medium of claim 19, wherein the instructions when executed by the processing device cause the processing device to perform operations further comprising estimating a voltage threshold (VT) distribution for the memory cells based on the debug data.
